(19) United States
(12) Patent Application Publication
(10) Pub. No.: US 2012/0167819 A1
(43) Pub. Date: Jul. 5, 2012

(54) METHOD FOR RECONSTRUCTING A SEMICONDUCTOR TEMPLATE

(75) Inventors: Karl-Josef Kramer, San Jose, CA (US); Mehrdad M. Moslehi, Los Altos, CA (US); David Xuan-Qi Wang, Fremont, CA (US); Rahim Kavari, Campbell, CA (US); Rafael Ricolcol, Hayward, CA (US); Jay Ashjaee, Cupertino, CA (US)

(73) Assignee: SOLEXEL, INC., Milpitas, CA (US)

(21) Appl. No.: 13/341,976

(22) Filed: Dec. 31, 2011

Related U.S. Application Data
(63) Continuation-in-part of application No. 11/868,493, filed on Oct. 6, 2007, now Pat. No. 8,035,028.
Application No. 11/868,493 is a continuation-in-part of application No. 13/209,390, filed on Aug. 13, 2011.
(60) Provisional application No. 61/429,033, filed on Dec. 31, 2010.

(51) Int. Cl. C30B 25/18

(52) U.S. Cl. 117/95; 117/97

(57) ABSTRACT

The disclosed subject matter pertains to deposition of thin film or thin foil materials in general, but more specifically to deposition of epitaxial monocrystalline or quasi-monocrystalline silicon film (epi film) for use in manufacturing of high efficiency solar cells. In operation, methods are disclosed which extend the reusable life and to reduce the amortized cost of a substrate or template used in the manufacturing process of silicon solar cells. Further, methods are disclosed which provide for the conversion of a low quality starting surface into an improved quality starting surface of a silicon wafer.

### CROSS-REFERENCE TO RELATED APPLICATIONS

This application claims priority to U.S. Provisional Patent Application Ser. No. 61/429,033 filed Dec. 31, 2010, which is hereby incorporated by reference in its entirety.

This application is also a continuation-in-part of U.S. patent application Ser. No. 11/868,493 (published as U.S. Pub. No. 2008/0289684), filed Oct. 6, 2007, and a continuation-in-part of U.S. patent application Ser. No. 13/209,390, filed Aug. 13, 2011, both which are hereby incorporated by reference in their entirety.

### FIELD

This disclosure relates in general to the field of solar photovoltaics, and more particularly to the field of repeatedly fabricating thin film solar substrates from a semiconductor template.

### BACKGROUND

Crystalline silicon (including multi- and mono-crystalline silicon) is the most dominant absorber material for commercial photovoltaic applications. The relatively high efficiencies associated with mass-produced crystalline silicon solar cells, combined with the abundance of material, garner appeal for continued use and advancement. But the relatively high cost of crystalline silicon material itself limits the widespread use of these solar modules. At present, the cost of “wafering”, or crystallizing silicon and cutting a wafer, accounts for about 40% to 60% of the finished solar module manufacturing cost. If a more direct way of making wafers were possible, great headway could be made in lowering the cost of solar cells.

There are several known methods of growing monocrystalline or quasi-monocrystalline semiconductors, such as silicon, and releasing or transferring the grown wafer. Regardless of the methods, a low cost epitaxial silicon deposition process accompanied by a high-volume, production-worthy, low cost method of forming a release (sacrificial lift-off separation) layer are prerequisites for wider use of silicon solar cells.

Another prerequisite is the availability of a re-usable template to repeatedly perform the sequence of release layer formation, thin film deposition, on-template processing, thin film layer release, recovery/reconditioning of template.

The microelectronics industry achieves economy of scale through obtaining greater yield by increasing the number of die (or chips) per wafer, scaling the wafer size, and enhancing the chip functionality (or integration density) with each successive new product generation. In the solar industry, economy is achieved through the industrialization of solar cell and module manufacturing processes with low cost high productivity equipment. Further economies are achieved through price reduction in raw materials through reduction of materials used per watt output of solar cells (also through elimination of consumption of expensive materials and replacing them with cheaper materials).

In order to achieve the necessary economy for the solar photovoltaics industry, process cost modeling is studied to identify and optimize equipment performance. Several categories of cost make up the total cost picture: Fixed Cost (FC), Recurring Cost (RC) and Yield Cost (YC). FC is made up of items such as equipment purchase price, installation cost and robotics or automation cost. RC is largely made up of electricity, gases, chemicals, operator salaries and maintenance technician support. YC may be interpreted as the total value of parts lost during production.

To achieve reduced Cost of Ownership (CoO) numbers required by the solar field, all aspects of the cost picture must be optimized. The qualities of a low cost process are (in order of priority): 1) High productivity, 2) High yield, 3) Low RC, and 4) Low FC.

Designing highly productive and economical methods and process equipment requires a good understanding of the process requirements and reflecting those requirements into the equipment architecture. High yield requires a robust process and reliable equipment and as equipment productivity increases, so too does yield cost. Low RC is also a prerequisite for overall low CoO. RC can impact plant site selection based on, for example, cost of local power or availability of bulk chemicals. FC, although important, is diluted by equipment productivity.

Thus, a high productivity, reliable, efficient manufacturing process flow and equipment is a prerequisite for low cost solar cells.

### SUMMARY

Therefore a need has arisen for high productivity thin film deposition methods and systems. In accordance with the disclosed subject matter, methods for the reconstruction of a reusable semiconductor template which provide significant cost reduction in the production of thin film semiconductor substrates (TFSSs) are disclosed.

The disclosed subject matter pertains to deposition of thin film or thin foil materials in general, but more specifically to deposition of epitaxial monocrystalline or quasi-monocrystalline silicon film (epi film) for use in manufacturing of high efficiency solar cells. In operation, methods are disclosed which extend the reusable life and to reduce the amortized cost of a substrate or template used in the manufacturing process of silicon solar cells. Further, methods are disclosed which provide for the conversion of a low quality starting surface into an improved quality starting surface of a silicon wafer.

These and other advantages of the disclosed subject matter, as well as additional novel features, will be apparent from the description provided herein. The intent of this summary is not to be a comprehensive description of the subject matter, but rather to provide a short overview of some of the subject matter's functionality. Other systems, methods, features and advantages here provided will become apparent to one with skill in the art upon examination of the following FIGURES and detailed description. It is intended that all such additional systems, methods, features and advantages included within this description be within the scope of the claims.

### BRIEF DESCRIPTION OF THE DRAWINGS

The features, nature, and advantages of the disclosed subject matter will become more apparent from the detailed description set forth below when taken in conjunction with the drawings, in which like reference numerals indicate like features and wherein:

FIGS. 1A-1C show one embodiment of the formation of surface features on a reusable semiconductor template;

FIG. 2A shows a patterned semiconductor template, a porous semiconductor multilayer, and a TFSS;

FIG. 2B shows an electron micrograph of a flat template and a sacrificial layer with two different porosities;

FIG. 3A shows a hexagonal patterned semiconductor template, a porous semiconductor multilayer, and a TFSS;

FIG. 3B is a photograph of the released hexagonal TFSS of FIG. 3A;

FIG. 4 shows an electron micrograph of the interface between a template and a TFSS;

FIG. 5 shows a TFSS ready to be released from a template;

FIG. 6A shows two templates with differing amounts of TFSS overdeposition;

FIG. 6B shows a TFSS being released from a template;

FIG. 6C shows a TFSS with overdeposition being removed from a template;

FIG. 6D shows the use of grinding tape to remove residual TFSS material from a template;

FIG. 6E shows the use of an edge grinder to remove residual TFSS material from a template;

FIG. 6F shows the use of a laser with a varying angle of incidence to remove residual TFSS material from a template;

FIG. 6G shows the removal of excess front-side TFSS material by grinding;

FIG. 7A-C depict main process steps of a three-dimensionally structured template as it is reconstructed in accordance with the disclosed subject matter;

FIG. 8A-B depict main process steps of a three-dimensionally structured template as it is reconstructed to mitigate a defective region; and

FIG. 9A-C depict key fabrication steps of the reconditioning of a wafer in accordance with the disclosed subject matter.

### DETAILED DESCRIPTION

Although the present subject matter is described with reference to specific embodiments, one skilled in the art could apply the principles discussed herein to other areas and/or embodiments without undue experimentation.

In operation, and particularly in the field of photovoltaics, the disclosed subject matter enables low cost fabrication of thin film substrates to be used for solar cell manufacturing by means of a template which can be used repeatedly to fabricate the thin film substrates. The field of this disclosure covers several apparatuses and methods for generating thin film substrates and for treating the templates which are used to produce the thin film substrates, with the goal of recovering the templates to enable an extended number of re-uses.

A process to produce thin film or thin foil epitaxial solar cells includes the use of single crystal silicon or suitable crystalline semiconductor material wafers as reusable templates. This disclosure includes process flows, methods, apparatuses, and variations thereof which enables the repeated use of a template that is used in the fabrication of thin film layers which subsequently are processed to become solar cells.

The subject matter of this disclosure may include a starting crystalline semiconductor wafer (called a template) with correct resistivity to enable anodization to form porous semiconductor material on one or both sides. The semiconductors used may include crystalline silicon, and in particular monocrystalline silicon. The template outline may be of any suitable shape, including round (with or without notches or flats), square, or pseudo-square with rounded, truncated, or chamfered corners; and the template may also be planar, substantially planar, or have a three-dimensional structure. The porous semiconductor material may consist of several layers with discrete or graded porosity. At least one section of the porous semiconductor layer system serves as a designated weakened layer that facilitates separation of the TFSS from the template.

This disclosure covers the use of a reusable template for repeatedly fabricating thin crystalline solar cell substrates from the template—during which the solar cell substrates may be fabricated on one side of the template or on both sides of the template. And even though the figures in this disclosure specifically address the single sided processing, it is envisioned that all embodiments of the current disclosure hold essentially for the case of single sided substrate processing as well as for double side substrate processing using both sides of the template to harvest solar cell substrates.

Regarding the starting wafer, several structural architecture options are described in the following; however the wafer and resulting template may be in any form, planar, textured, or having any three-dimensional structure. In the simplest embodiment, the template may be essentially flat, i.e. the surface may be of any chosen surface quality, such as for example as-sawn with saw damage removed, lapped or ground, etched, grinded, or even mirror polished. In another embodiment, the wafer may be textured, using for instance alkaline random texturing before the formation of the above-described porous semiconductor layer system. By this means, a textured surface is then transferred directly onto the thin film solar cell substrate. As a third alternative, the template may be a three-dimensional structure generated using processing such as patterned wet or dry etching. This template with three-dimensional pattern may be achieved through the use of patterning technology, such as, but not exclusively, photolithography and wet or dry etching.

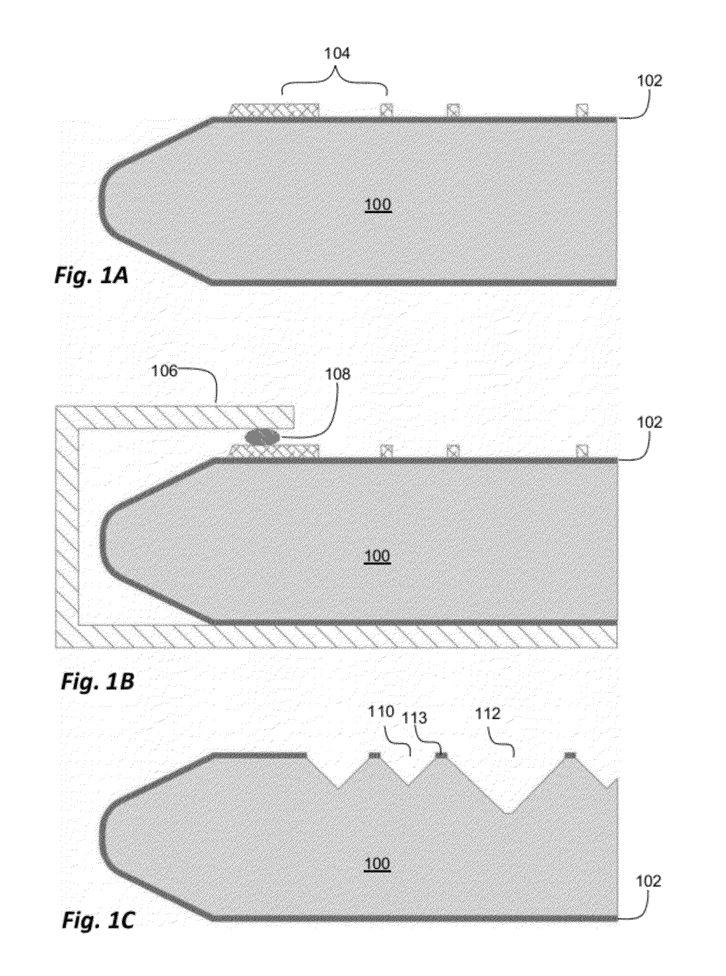

An example process is described in FIGS. 1A-1C for the formation of a three-dimensional template. In FIG. 1A, a starting wafer 100 is provided. For the purpose of forming a 3-dimensional structure, typically, a hard mask is formed, using as materials for example, but not exclusively, thermal oxide or other deposited etch resistant layer or layers such as deposited silicon nitride or silicon di-oxide. Shown, hard mask layer Si0₂ 102, is formed on the surface of wafer 100. Then the desired pattern of photoresist 104 is lithographically patterned onto hard mask layer 102. In FIG. 1B, the wafer is placed in a holder/chamber 106 and sealed with O-ring 108 to protect all but the front surface. Then hard mask layer 102 is etched to produce the desired pattern, removing all hard mask except what lies underneath the remaining photoresist.

In FIG. 1C, a semiconductor etch process is employed, either through dry etching, such as deep reactive ion etching (DRIE), or wet etching such as using an optionally heated concentrated alkaline wet etch with chemicals such as potassium hydroxide, sodium hydroxide, tetramethyl ammonium hydroxide (TMAH) or others. This creates the desired pattern on the surface of the wafer—as shown in the example of FIG. 1C which includes large inverted pyramidal structures 112 and small pyramidal structures 110 defined by ridges 113. Finally, the photoresist and hard mask are stripped from the wafer, and the wafer is cleaned. It is then ready for the formation of porous semiconductor on the textured surface. Other similar processes are easily derived from the figures by those skilled in the art.

A three-dimensional template patterning is depicted in most figures of this disclosure as it encompasses a larger realm of embodiments. However, unless otherwise noted, the figures, process flows, methods and apparatuses of this disclosure are equally applicable to flat or randomly textured templates.

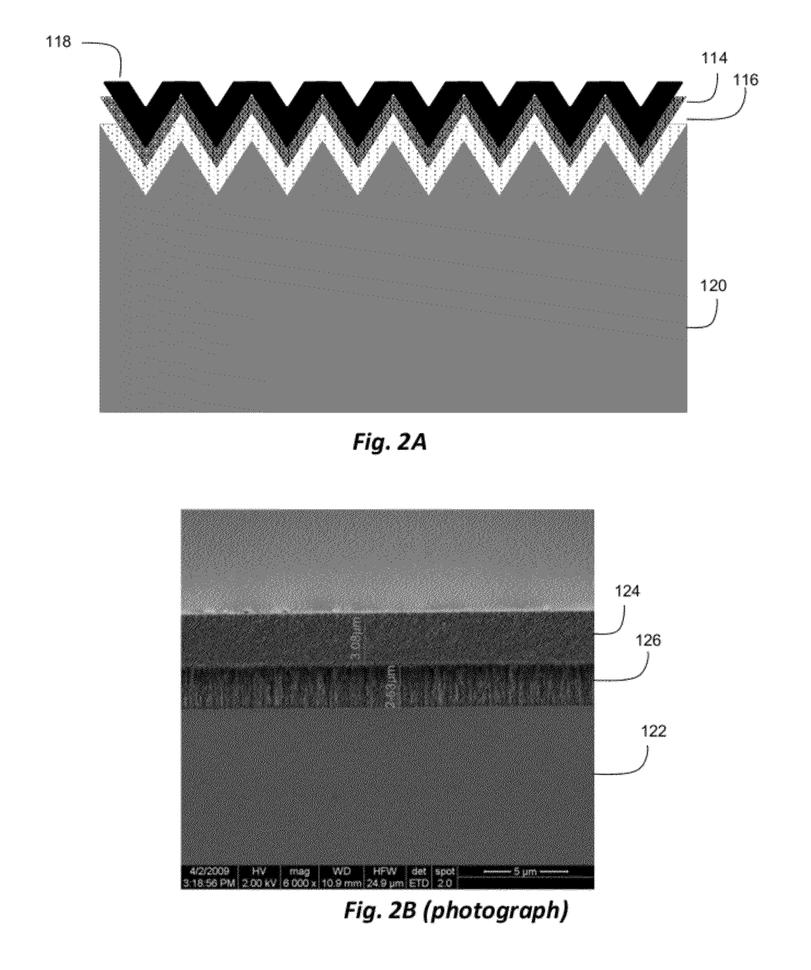

Using either a patterned or an un-patterned template, the subsequent process step is porous semiconductor formation (by anodization such as a wet anodic etch in an HF-based chemistry), followed by rinsing and drying where necessary. Porous semiconductor such as porous silicon on a crystalline silicon template is to be formed on at least one side of the template. In the case that the semiconductor is silicon, the process of forming porous silicon has been described in previous disclosures, for example U.S. Patent Publication No. 2011/0030610, which is hereby incorporated by reference. As shown in FIG. 2A, the porous semiconductor formation may entail the fabrication of at least one low current, lower porosity region 114 at the surface and at least one high current, higher porosity layer 116 closer to template 120. Importantly, a single porosity layer or a graded porosity layer may also be employed.

The template, having the porous semiconductor layers formed, may then be transferred to an epitaxial deposition reactor, in which an epitaxial layer is deposited at least on one side of the template. FIG. 2A illustrates the deposition of epitaxial layer 118 on top of the porous semiconductor layer system. FIG. 2B is a photograph of a porous semiconductor bi-layer structure on flat template 122, with lower porosity layer 124 on top and higher porosity 126 below.

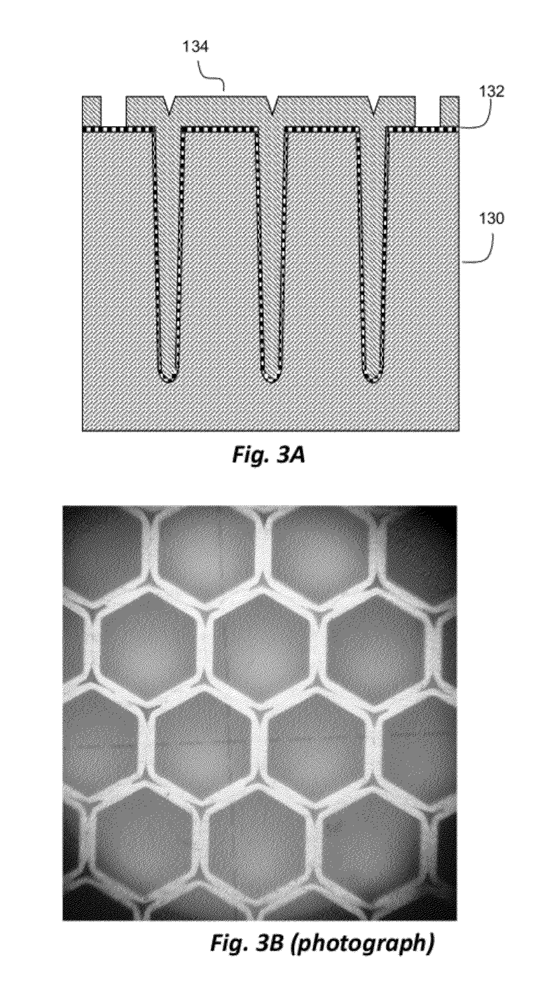

FIG. 3A is a drawing illustrating the deposition of epitaxial silicon layer 134 on porous silicon layer 132 formed on three-dimensional hexagonal template 130. FIG. 3B is a top view photograph of a released epitaxial thin film silicon layer, such as epitaxial silicon layer 134 in FIG. 3A, after release from the hexagonal template.

Before the epitaxial deposition, either during the ramp-up phase or during a separate pre-deposition time, the template is heated in a hydrogen ambient which serves several purposes: the top layer of the porous semiconductor is reflowed to re-form a quasi-monocrystalline growth surface and ultrathin seed layer of semiconductor (QMS). Also, the hydrogen bake serves to reduce any oxidized surface semiconductor back to its elemental form. In addition, the high porosity semiconductor layer coalesces to form a weak layer which can later serve as the release boundary between the grown layer and the template.

If the semiconductor is silicon, then in the initial stages of the deposition or during the bake, the reflow can be assisted by small amounts of a non-chlorine-containing species such as silane or using very low flow quantities of other silicon-containing gases such as trichlorosilane (TCS). This is one option for a process component that serves to safely prevent a failure mechanism that may occur during imperfect reflow and which is described below. Other problems and failure mechanisms that may occur during reflow have been described U.S. patent application Ser. No. 13/209,390 filed on Aug. 13, 2011 which is hereby incorporated by reference.

There are potential failure mechanisms that may occur during reflow. Solutions to such failure mechanisms are part of this disclosure: as the template is heated up in the semiconductor deposition reactor, which can for example be an epitaxial reactor, the template touches the susceptor typically in a plurality of locations. These contact points can contribute to a non-ideality in the above-described reflow of the porous semiconductor layer. These contact points may also contribute to a local abrasion of the porous semiconductor layer. As a consequence, the porous semiconductor layer may contain local areas where it is not hermetic.

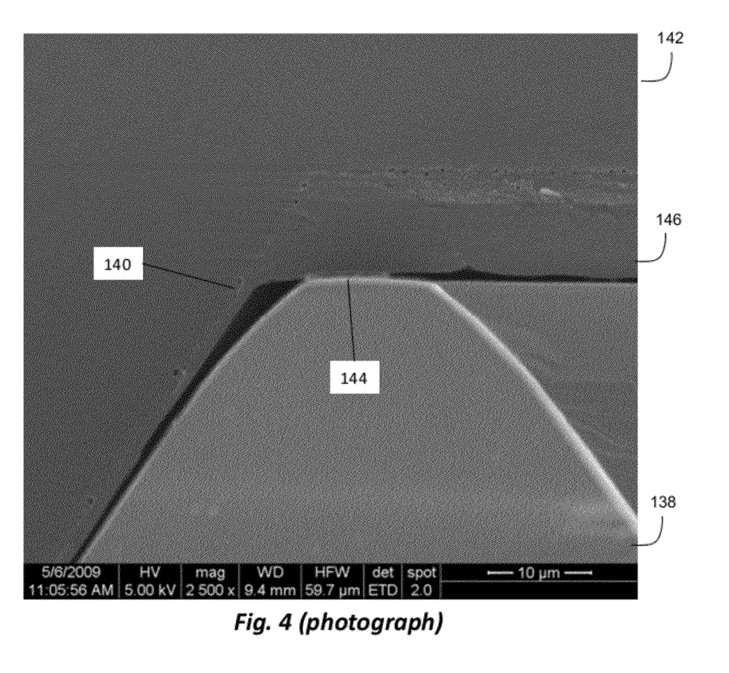

An example of a failure mechanism is illustrated in the photograph of FIG. 4, which shows template 138, QMS layer 140 (which normally contains some entrapped holes), and deposited epitaxial layer 142. As the deposition starts after the reflow, two phenomena can be observed: a) deposition of material through QMS layer 140 and directly onto the template base. Fused spot 144 is an example of this phenomenon. Such areas lack a weakened sub-layer and thus resist the subsequent release process (described below). In cases where shortly after the onset of deposition, the non-hermetic region is sealed, there is a chance that deposition gas may be trapped in underneath the top deposition layer. Such deposition gases may contain etching components such as chlorine-containing species as byproducts of the deposition reaction of silicon from a TCS molecule. These byproducts can contribute to subsequent etching of the template material. The etched and volatized template material can redeposit on the top layer, thus re-releasing again the chlorine-containing species. In FIG. 4, some re-deposited template material 146 may be seen. Thus, in a quasi-sealed local environment the process can continue and template etching can be observed to be severe, up to several microns. One option to avoid this etching and re-deposition mechanism is to start the deposition using a reactant which does not have an etching species as a byproduct. An example for such a reactant is silane, in the case of silicon deposition. Another option to avoid both the deposition directly onto the template and the local etching of the template is the proper formation of the contact area that the template shares with the susceptor. Low contact area in conjunction with suitably large radii at the contact area are preferable. This, in conjunction with suitable heater arrangements, is required to enable a uniform thermal ramp and profile within and between templates.

As for the epitaxial deposition process, the TFSS that is deposited epitaxially may contain an in-situ emitter, deposited in situ in the semiconductor deposition chamber. The emitter may also be added later as an ex-situ emitter outside of the epitaxy chamber. The structure on the template may be with the emitter up (emitter last during deposition) or down (emitter first during deposition). The epitaxial or non-epitaxial deposition may or may not contain a suitable dopant gradient designed to aid the desired flow of generated carriers through the device.

This so fabricated layer structure of deposited semiconductor on a weakened layer on a high temperature capable template is extremely valuable. It allows for carrying a thin film on a solid template and allows much flexibility for what is in the following called on-template processing.

In such on-template processing, the template serves as a carrier to move and support the thin and fragile TFSS throughout several on-template process steps, including but not limited to the following: thermal processes such as oxidation or film deposition, including but not limited to thermal oxidation; pulsed nanosecond (ns), pulsed picoseconds (ps) or other laser processes, such as scribing, doping, or ablation; chemical vapor deposition (CVD) and physical vapor deposition (PVD) processes; lithography, screen printing, stencil printing, ink jet printing, aerosol printing, spray coating or etching, ion implantation, immersion or single side clean, etch or deposition (such as plating), lamination, die attach or bonding, releasing, wet chemical texturing or dry texturing of the surface, rinsing, cleaning and drying of the surface. A unique quality here is that the template is clean and solar-cell-compatible, rigid and sturdy, high-temperature-capable, and reworkable.

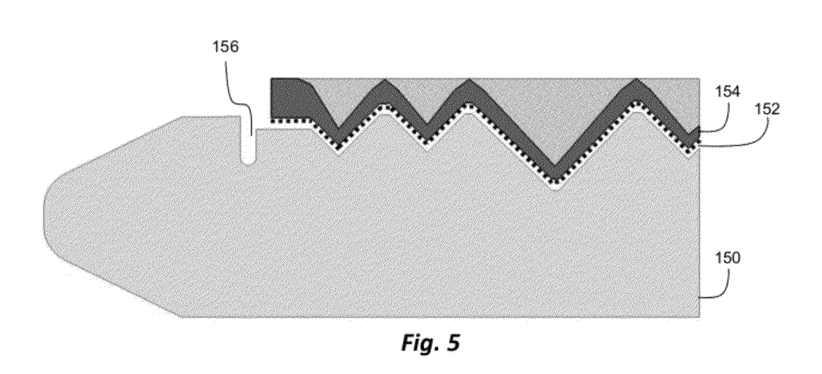

After suitable on-template processing, the TFSS can be released from the template carrier (optionally after its reinforcement with a backplane sheet laminated to, coated or printed on or otherwise applied to the TFSS). A conceptual diagram of the release of TFSS 154 from template 150 along sacrificial porous layer 152 is shown in FIG. 5. The release can be carried out either with or without the use of a temporary or permanent reinforcement plate or sheet, which is attached to the epi layer prior to the epi release. The reinforcement plate or sheet may or may not at this point or later contain structures, such as dielectrics or electrically conductive cell interconnect materials. If used, the reinforcement plate may contain perforations or otherwise a plurality of electrically conductive locations enabling the electrical contacting of the TFSS through or around the reinforcement plate, such perforations being present either at the time of TFSS release or formed at a later point. Suitable reinforcement materials may include silicon, glass, silicon-aluminum alloys, plastics or polymers such as prepreg or other dielectric adhesives, metals such as aluminum, ceramics or combinations thereof. At a suitable point prior to release, the definition or border cutting of the TFSS area to be released can be accomplished for instance using a laser. FIG. 4 shows border cut 156 surrounding TFSS 154.

This border cutting can be performed before or after the release of the TFSS. It may be advantageous to do cutting both before and after the release, depending on reinforcement process and materials. The border cutting also serves to weaken the thin TFSS and thus facilitate easier release. Another potential method for facilitating easier release is the use of a grinding or otherwise abrasive method, preferably applied to the edge of the template. By doing so, the TFSS epitaxial layer region at the edge of the template can serve as the weak point, from which release can be initiated. Such pre-release grinding can also facilitate the flow of air into the weakened area between TFSS 154 and template 150, thereby allowing pressure equalization and removing pressure-differential-induced resistance to the release motion. The release itself can be carried out by exploiting the presence of local weak areas which serve as initiation locations for the release.

Optionally, a pulsed force, for instance by pulsating the vacuum on either side of the template and substrate sandwich, can be applied. In this way, the release process can be extended across location and time (not unlike opening a zipper), rather than having to overcome the whole area bond force plus the atmospheric pressure holding force on the template. Alternatively, the release can be initiated at an edge or a corner of a substrate and then proceed from there, while in the process keeping the template and the partially released TFSS essentially parallel, in order to avoid small curvature radii, which can contribute to excessive stresses and potential cracking of the active TFSS layer.

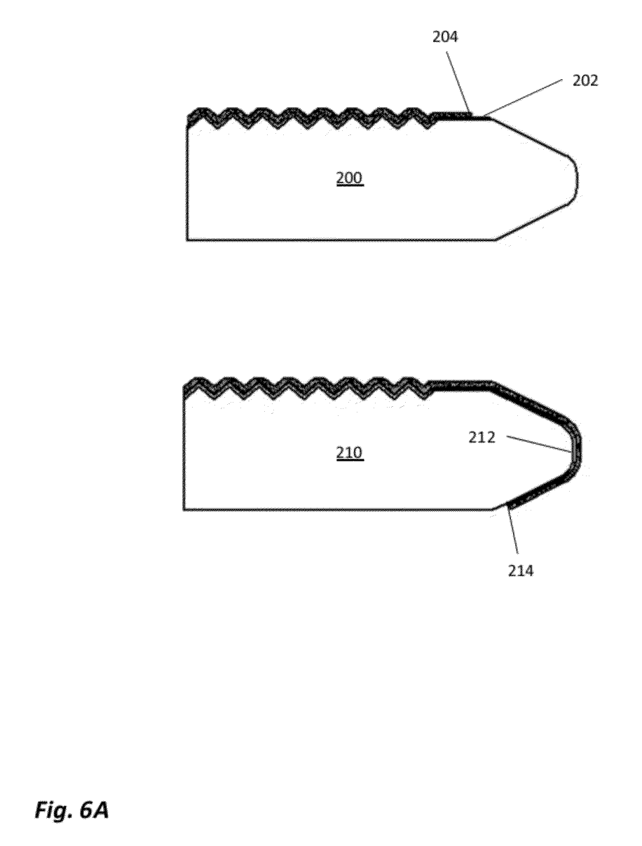

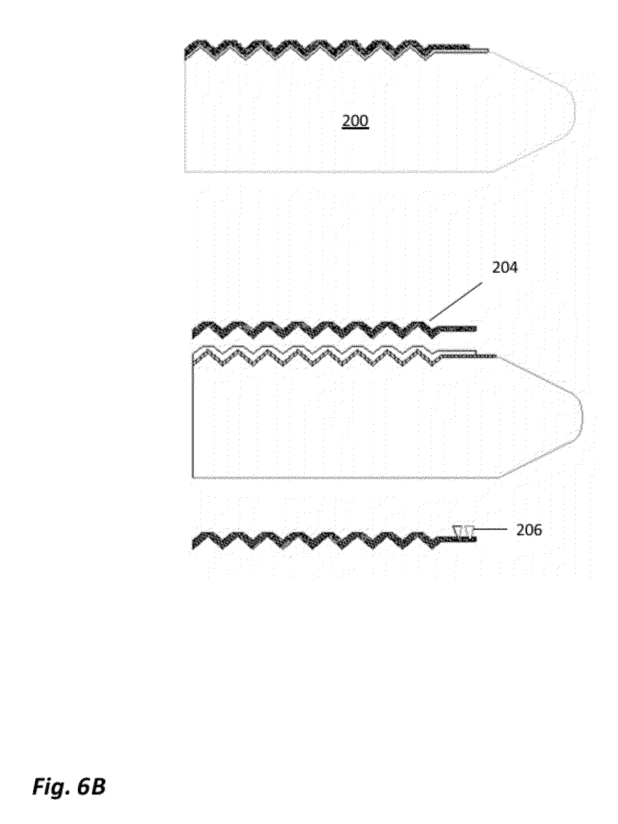

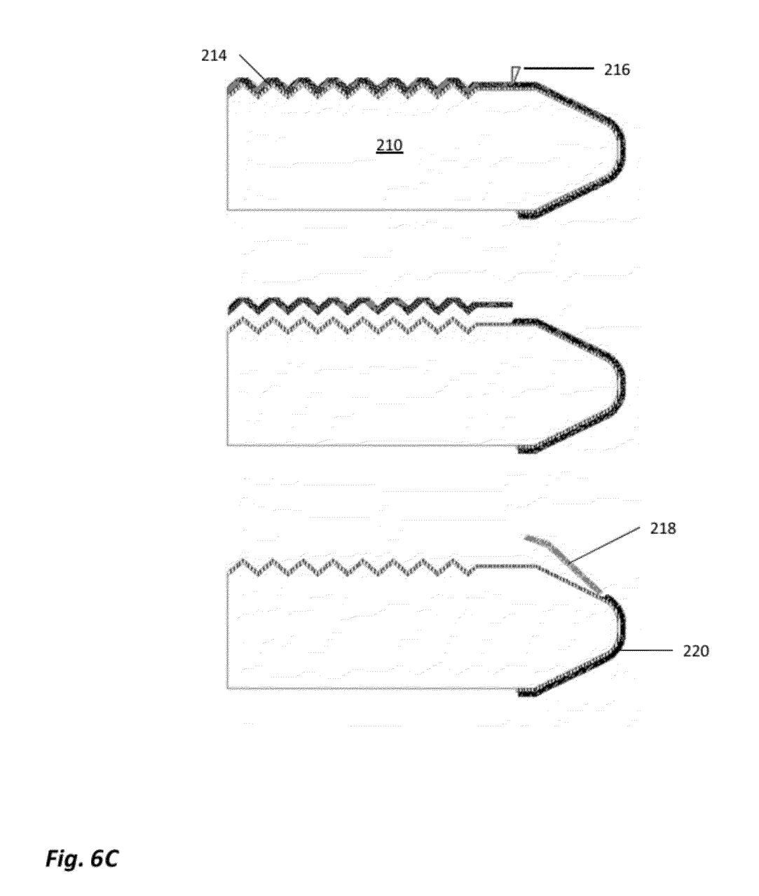

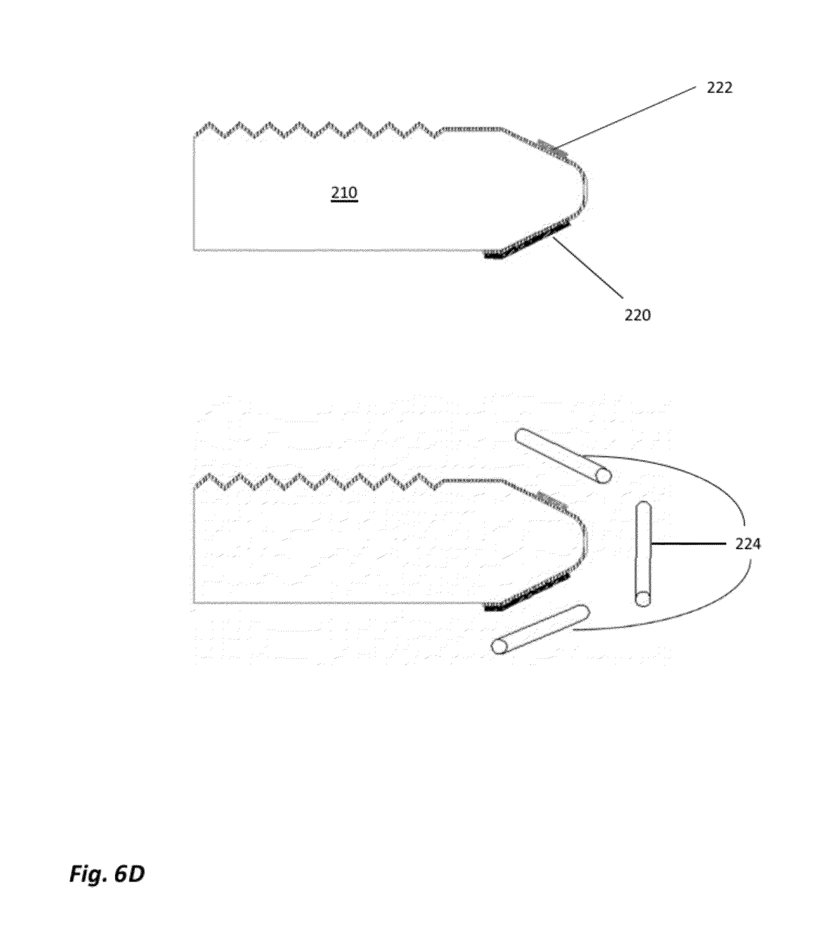

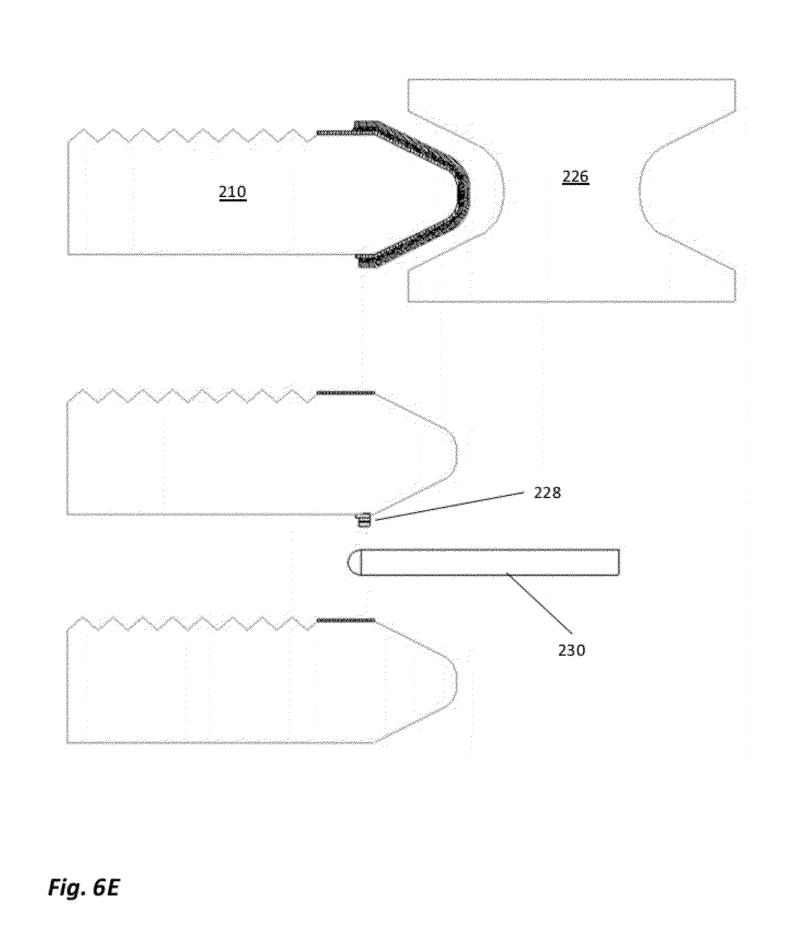

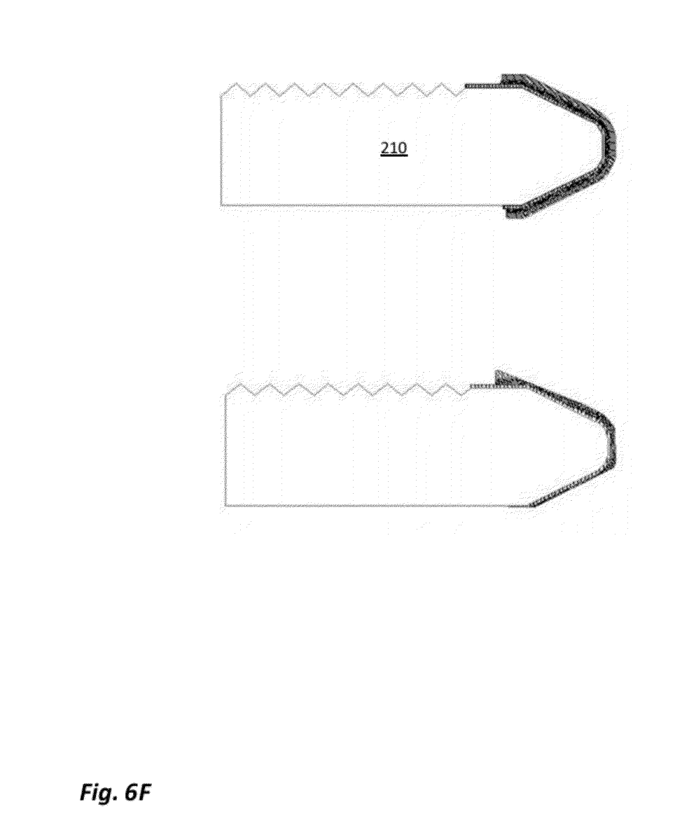

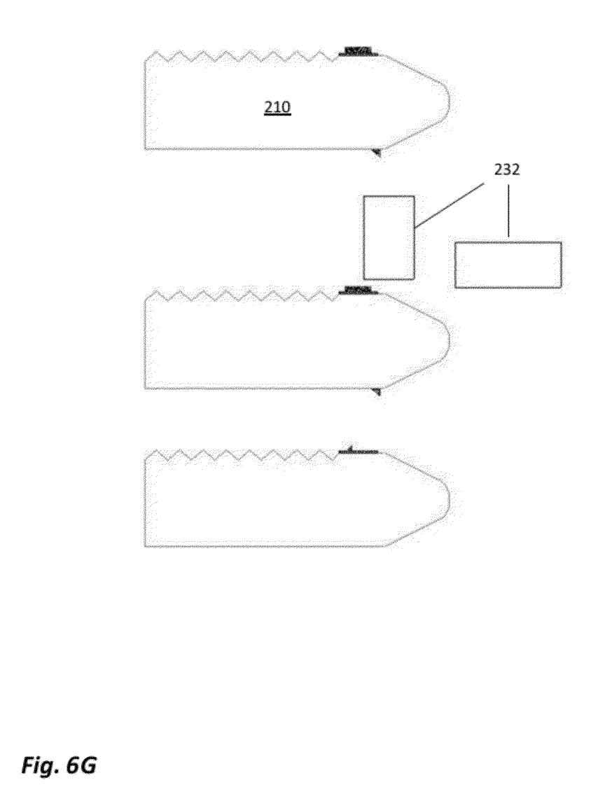

After release of the active TFSS there may be residual deposited thin film that is remaining outside of the active area, especially if the template is somewhat oversized with respect to the active TFSS. FIG. 6A shows two possibilities. Template 200 has a layer of porous semiconductor 202 which extends beyond the edge of TFSS 204. This does not present a problem for release.

However, a typical CVD deposition process can deposit material not just on the front side, but depending on the design, also on the edges and the back side of the template. The extent of the film coverage is illustrated in template 210. Thick deposition of semiconductor layer in the bevel area can be undesirable. Depending on the process, deposition on the backside can be detrimental for subsequent processing, or desired, if the backside deposition yields a comparable film to the front side deposition in the case of double side processing. Several precautions may be taken in order to wind up with a template like template 200 instead of template 210. One mode for avoiding or minimizing backside and bevel deposition is to use a neutral gas, such as hydrogen, as a purge gas in the vicinity of the edge and the backside of the template during the deposition step. Another mode for avoiding or minimizing backside and bevel deposition is to use a shadow mask that shadows the area where deposition is not desired from the deposition gas. A third mode for reducing backside and bevel deposition is to use susceptor designs with large surface area or otherwise optimized geometries which can serve to preferentially deposit material from the gas phase, thereby depleting the deposition gas in areas where deposition is not desired. Deposition processes may have preferred locations and directions where more or less material is deposited in undesirable areas. It may be advantageous to symmetrize the deposition of the undesired material across several re-uses of the same template. For that purpose, the template orientation can be tracked where needed, and dedicated changes of orientation or location can be programmed as part of a production flow.

In template 210, porous silicon layer 212 wraps partially around the edge of the template, but TFSS 214 wraps around even farther. Under circumstances where the TFSS extends beyond the edge of the porous semiconductor, other methods may be employed to remove the section of the TFSS that directly contacts the template.

FIG. 6B demonstrates TFSS release in the case of template 200. TFSS 204 is released, leaving little or no edge debris. After release, TFSS 204 may be cut to size by laser 206.

FIG. 6C shows template 210, the case where the TFSS extends beyond the edge of the porous semiconductor layer or where the porous semiconductor is not formed with porosities or thickness in the bevel region that are adequate for easy release of the TFSS. TFSS 214 is cut to size by laser 216 and then released from template 210. After release, a residual film must be subsequently removed. Section 218, which is bonded to a porous semiconductor layer and not directly to template 210, may be removed by use of compressed air, high or elevated pressure water or other suitable fluid, a taping-detaping process, by sonic (ultra- or megasonic) energy, or by a machining process such as grinding or lapping the residual film off the template. The grinding can for instance be accomplished using a grinding material that is abrasive and has a suitable hardness with respect to that of the semiconductor or by a soft material, which shears off the excess thin film deposit. The latter makes use of the fact that the bond force of the excess material is lower and governed by the weakened layer between the thin film and the template. The removal of excess thin film can also occur by suitable chemical etching. Suitable chemical etching can be selected to yield good dopant concentration or composition based selectivity between deposited film and template. It can also make use of a directed, localized etch.

The removal of the residual deposited thin film can be accomplished on a single wafer basis or in a batch mode. The removal processes described so far are designed to remove material at least in the flat part of the template outside of the active area and extending onto the bevel of the template at the bevel edge. Other methods may be used to remove the remainder 220 of the TFSS that is bonded directly to template 210 due to local lacking or imperfect quality of the porous semiconductor layer.

Independent of the precautions mentioned above, it may be advantageous to remove excess deposited material in the bevel or the backside area. This removal of excess deposited material may be carried out after each re-use cycle or after several re-use cycles and may be repeated throughout the lifetime of the template. FIG. 6D shows the use of grinding tape 224 to remove remainder 220 and local imperfection 222, and FIG. 6E shows the use of a machine tool for a grinding, polishing, or otherwise abrading device. With such a device, the excess deposited material in the bevel or backside area can be reduced or completely removed. For the case of the tape based grinder, the template may be spun in the presence of a tape, which is typically embedded with diamond or silicon carbide. For non-round template geometries, such as squares or pseudo-squares, the removal setup should be a different one, where, for instance, the template would not be spun, but moved from side to side, swiveled, or oscillated; or the tape holding/feeding mechanism may be moved, swiveled or oscillated. The removal process can be tuned to preferentially remove material in areas where more excess material has been deposited. Removal of deposited material at the different points around the bevel or backside area are accomplished by applying the tool, tape or sheet at different angles, pressures or positions towards the template. Other removal implementations for deposited material will be apparent to those with ordinary skill in the art. An alternative process to this type of mechanical removal of excess deposit from the template is the use of suitable chemistry which is applied locally with the goal of removing the excess deposit from the template.

In FIG. 6E, precision grinding wheel 226 (or a polishing wheel or slurry) is used to remove the film around the edge of template 210. However, this may leave backside residue 228, which may then be removed by, for example the use of backside grinder 230. It is also envisioned to combine the function of a bevel grinding wheel with that of an edge backside grinding wheel into one tool.

Another alternative process to the tape, sheet or precision bevel grind/polish step is the use of a laser, either direct or water-jet-guided, to remove excess deposition at the bevel and the underside of the template and reshape the bevel. The effect of a laser based bevel material removal process is shown in FIG. 6F. This method may have the advantage of allowing particularly precise dimensional control. A combination of the above methods is also likely. As shown, little or none of template 210 has been removed by the laser edge ablation employed in FIG. 6F.

In some cases, the processes described above in conjunction with FIG. 6C-6E will still leave some unwanted additional TFSS material on the front side of the template as well as the back side. In this case, as shown in FIG. 6G, grinders 232 may be used to remove that material. If this is not done, the remaining front side TFSS material may cause the next TFSS produced on template 210 to “lock” to that point, making release more difficult. By removing the excess material before reusing the template, this concern may be alleviated.

After the removal of the undesired TFSS material by whatever method, a typical flow may include re-use cleaning, which serves several purposes: first, to bring the template into a re-usable condition, capable of withstanding repeated re-uses; second, to remove remnants of the sacrificial release layer; next, to remove metallic contaminants that would be detrimental to the lifetimes of the subsequent TFSSs to be deposited on the same template; and finally, to remove detrimental remnants of any on-template processes, such as organic or metal-containing residues. Typically, after the re-use cleaning, the template is subjected again to the porous semiconductor formation process, thereby forming another sacrificial release layer. This is then again followed by the deposition of the thin film to be released. Subsequent processing continues as described above.

Residual deposition extending onto the backside of the template may be detrimental to further processing and may accumulate as the template is subjected repeatedly to the sacrificial layer formation/deposition/further processing/release/post-release treatment processing. Residual deposition on the backside can cause local stress points and unsmooth template surfaces which are detrimental to handling and which may increase the propensity of the template to break. Therefore, the avoidance (described above) or removal of backside deposited material may be advantageous. This may be carried out after each re-use cycle or after several re-use cycles and may be repeated throughout the lifetime of the template. These methods can be done either by removing material from the complete backside area or by removing only locally at the wafer edge the material deposited mainly at the edge of the backside.

The template is a highly valuable commodity in the overall process. Therefore, any process that serves to extend the potential number of deposition cycles (template reuse cycles) that the template can sustain adds substantially to the value proposition (by reducing the amortized cost of template per cell). Therefore, in the case of defective processing on the template or incomplete release or removal of the TFSS film, the template can be subjected to a reconditioning process. This reconditioning process may consist of grinding and/or polishing of the full area of the template or of only the problematic portions of the template. After successful reconditioning, the templates can be re-entered into the process loop and re-use can be resumed.

Grinding and/or polishing can be accomplished using a single side or double side grinder/polisher. The grinding/polishing process is chosen according to the necessity of surface finish. The TFSS described above which later forms the substrate for the solar cell does not rely on a mirror polished surface finish of the substrate. It is therefore important to point out that the porous semiconductor sacrificial layer can be formed on a template surface that does not have to start out as a mirror polished semiconductor surface. As it is not known beforehand at what stage an imperfect processing of the substrate occurs and as an HVM-compatible grind/polish process uses up the least amount of material from the starting template if the thickness is known, it is advantageous to inspect the templates at one stage subsequent to the release process, and sort them into thickness ranges, such that a multitude of templates can be processed in a grinder/polisher at the same time, to the same target thickness. The above sorting for thickness and for local residue from the deposition can be done concurrently with suitable equipment, such as optical, capacitive or gas back pressure based sensing.

The TFSS that was released from the template carrier and which may already have several processes applied to it while on the template can be processed further after the release. There are several possible embodiments for the TFSS and its further handling: for sufficient layer thickness, the TFSS can be self-supporting and handled through further processes as is. If the template that was used to deposit the TFSS material onto was structured to form a three-dimensional structure, such as an array of pyramids, prisms or other three-dimensional geometries, then the TFSS may be self-supporting even if the amount of deposited TFSS material is very small. This structural feature is a potential advantage of the three-dimensional template and TFSS. If the layer thickness is not sufficient for the TFSS to be self-supporting, then the TFSS can be supported during further processing via a suitable support plate, sheet or film.

The following description and corresponding figures, not limited to the above, relate more directly to the subject matter disclosed in the present application. An aim of the disclosed methods is to extend the useful life cycle of these templates and to lower the amortized cost of manufacturing and using these templates. This may be achieved by adding like material, herein referred to as “reconstructing material”, with like doping, or at least suitable doping, to form porous semiconductor/silicon by anodization (or anodic etch) onto these templates by means of epitaxial deposition with suitable doping level. For instance if the starting template is comprised of p+ doped silicon, the epitaxial film is also going to be in-situ-doped with a p-type dopant such as boron (p+) and the added reconstructing material will appropriately doped (p+ doped) to form the porous layer using an anodization process.

Such deposition process may be used whenever necessary or advantageous—such as once every template reuse cycle or preferably once every multiple template reuse cycles or when the template thickness is lower than a desired value, in order to add thickness and material strength.

In general, such reconstructing material may: a) prolong the useful life of a template (in terms of the useful number of template reuse cycles) that is defective or too thin; b) provide a thicker template allowing the template to offer a longer useful life cycle and providing a lower amortized template cost per cell; c) provide a smoothed surface for subsequent processing by improving/planarizing the surface of the starting wafer; and d) provide a more even template thickness range throughout the life of the template and thus minimize process variabilities that can be caused by excessively different template thicknesses, such as, but not limited to those variabilities that relate to the thermal mass of a template

As described previously, after the TFSS is released from the template then the template may be treated with further process steps, using surface etching/cleaning and other processes to enable it to repeatedly undergo this same porous silicon (PS) formation, TFSS deposition, on-template processing including the optional application or attachment of a supporting backplane, removal process, reconditioning process. During these cycles, the template loses thickness.

However, there is a practical limit to the tolerable template thickness loss and because of material thickness loss, template strength will be decreased and the rate of breakage of templates may become excessive, resulting in substantial yield losses.

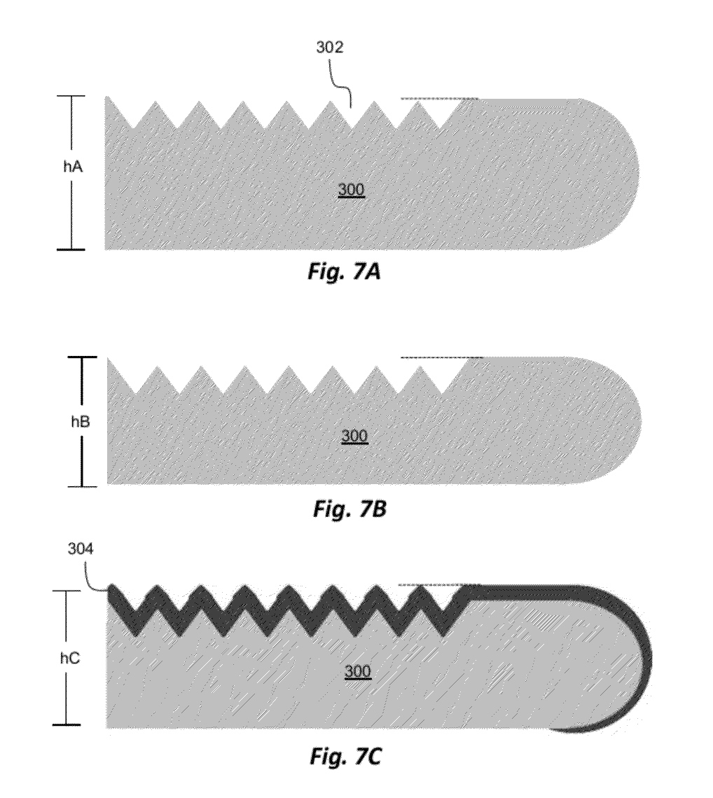

In order to avoid these disadvantages of template thickness loss, the disclosed methods extend the life of the template by thickening it up with a crystalline, preferably epitaxial or otherwise quasi-epitaxial film of like doping. A quasi-epitaxial film is hereby defined as a film that is grown on a template which itself is a quasi-monocrystalline template, such as from a silicon wafer generated from a quasi-monocrystalline ingot. This process is outlined generally in FIG. 7A-C which depict a three-dimensionally structured template as an exemplary embodiment and planar, substantially planar, and randomly pre-textured templates may also employ the same methods. As template 300 goes through TFSS fabrication processes, the thickness of the template, shown in FIG. 7A as original thickness hA, decreases to smaller thickness hB as shown in FIG. 7B. (For clarity of illustration thickness reduction is not shown to scale). Note in FIG. 7A the ridges of the three-dimensional structures, inverted pyramids 302, are on an equivalent plane with the flat front side template edge (the edge is the non-used portion of the template). However, in FIG. 7B, after the template has been thinned from anodic etching and/or wet etching the ridges of the three-dimensional structures are not an equivalent plane with the flat template edge—they are substantially lower. The thickness of the template may then be increased by epitaxially depositing like material 304 to the template which increases the template thickness, shown in FIG. 7C as hC. Shown, reconstructing semiconducting material 304 is of the same type and doping concentration as the starting template shown in FIG. 7A. Also note that the ridges of the three-dimensional structures have been restored to be on an equivalent plane with the flat template edge. Thus, the template thickness and three-dimensional structure have been recovered by the deposition of a layer of like material on the template top surface (used for the formation of PS).

Importantly, the methods provided may be applied to a template or wafer with any three-dimensional surface topography—typically a three-dimensional surface topography comprises cavities defined by ridges forming the opening of the cavities on the surface of the template.

The thickening process may be carried out multiple times during the life cycle of a template. Thereby adding a large value to the template, especially if the expitaxial deposition process on a given template can be done in a more cost-effective way than producing the starting template by wafering processes. A periodic or otherwise regular thickening of a template, for instance after a fix number of re-uses or when thickness drops below a certain threshold, is advantageous for the sustainment of a production line and for retaining tight control over processes such as thermally driven annealing, growth or deposition, printing or lithographic processes, lamination, and other processes that benefit from a smaller range of thicknesses.

As a variation, it is possible to start out with a more lightly doped template and only dope the area that undergoes the subsequent anodization cycles more highly (depicted in the figures as the top surface of the template) through the epitaxial deposition of the thickening layer. This may allow the utilization of a lower cost starting template as the price of semiconductor wafers is typically affected by the amount of dopant. Also, throughout an ingot, the doping level typically undergoes a significant profile. Thus, the impact these doping variations have on the formation of a TFSS, potentially throughout the lifecyle of the template and the formation of numerous TFSS, may be reduced by depositing reconstructing material only on the template surface layer that is to be anodized to form the porous layer. Another embodiment involves starting out with a higher doping concentration for the template and depositing a lower doping concentration at the surface. While potentially adding to template cost, such an arrangement allows for a very effective equalization of the electric field across a wafer during the anodization process which is used to form the porous semiconductor layer or layers.

Other benefits to depositing a relatively thick layer of epitaxial silicon onto the template to thicken template thickness include smoothing process imperfections which may be encountered throughout the cycles of re-uses of the template.

First, as part of the removal of the thin film (TFSS) from the template, a cutting process, using for instance, but not exclusively lasers, may be employed. This cutting process may intentionally or unintentionally due to variations generate cuts and marks on the surface of the template. These cuts may be smoothed out by subsequent etching, to provide a crystalline growth surface. The thick epi deposition for thickening is used to planarize the new starting surface—thus preventing subsequent negative impacts of the cutting marks.

Second, because in general there can be areas/regions on the template where, due to either handling, contact forces from carriers or susceptors, or due to particulate contamination, the PS anodized layer is not perfect. Then, during the baking process before epitaxial TFSS deposition the top layer does not reflow perfectly in the affected areas. This may lead to zones on the template where the perfect removal of the TFSS is no longer possible because part of the TFSS is locked to the template. Template edge areas are especially prone to such occurrences. Because the TFSS generally does not have the right doping to enable subsequent PS formation, the locked area is likely to increase, both in height and width, as surrounding areas do not get optimal current density during anodization and as silicon deposited on locked areas will itself provide holding forces that resist the removal of surrounding TFSS material.

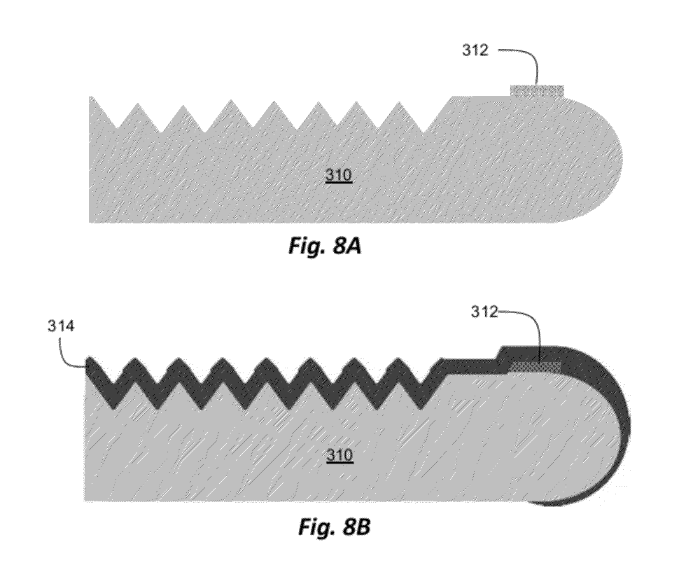

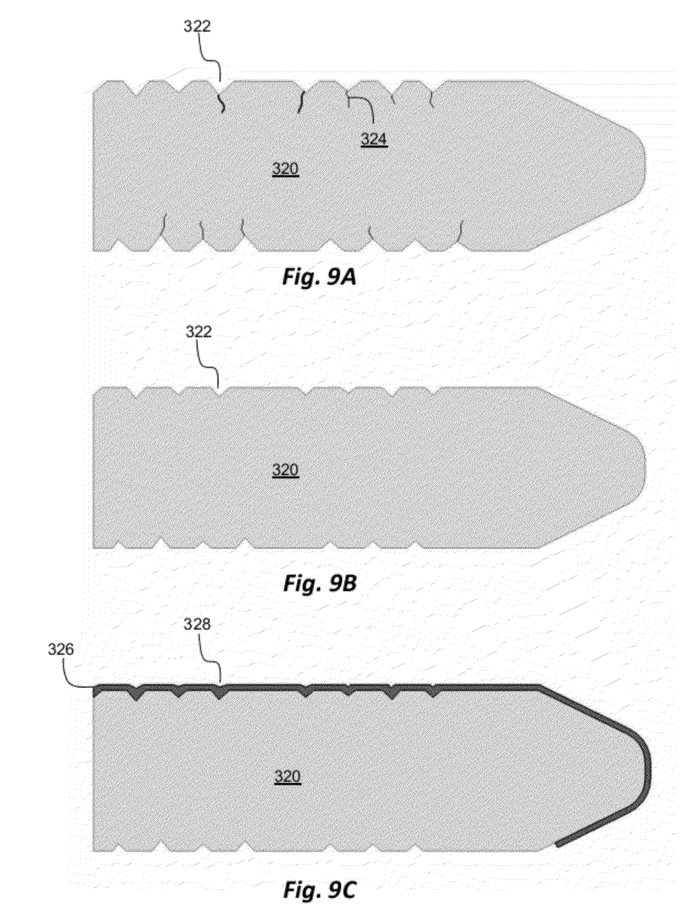

Depositing a thick epitaxial film of the right doping concentration to form PS again may render such defective spots/regions suitable for release again. This process is depicted in FIG. 8A-B in which a three-dimensionally structured template is depicted, however the same concepts apply to a substantially flat or randomly pre-textured template. FIG. 8A shows template 310, after several TFSS fabrication and re-use cycles, with residual epi layer 312. Residual epi layer 312 has the wrong doping concentration for PS formation and will become a permanent defect in the TFSS formation process as not porous semiconductor or porous silicon may be formed on this layer.

In FIG. 8B, epitaxial growth layer 314 has been formed over residual epi layer 312 as well as the rest of the template surface used for PS formation (the top surface). Epitaxial growth layer 314 has suitable doping for porous semiconductor/silicon (PS) formation and allows for the formation of PS over the entire template surface thereby mitigating the defective residual epi layer 312 and allowing for effective and clean release of the TFSS from the template.

The epitaxial deposition of the thickening layer may optionally be followed up by a treatment to the beveled edge of the template to remove the thickening layer over the beveled edge. This additional treatment may reduce the sharp facets at the edge which are a part of epitaxial growth characteristics and which can for instance be detrimental to template strength.

Such edge treatment may be carried out in multiple ways, such as edge bevel grinding/polishing via a tape or via a grinding/polishing wheel, or via a laser edge beveling process, or via chemical etching close to the template edge. These same methods, together with area grinding/polishing may also be carried out at the edge of the backside of the template in order to reduce the effect of any backside deposition at the template edge.

Monocrystalline or quasi-monocrystalline semiconductor wafer manufacturing cost is often governed by the processes associated with the manufacturing steps such as starting material cost, ingot growth—typically performed by Czochralski growth or by casting, the latter potentially as a monocrystalline-seeded quasimonocrystalline ingot—then cropping, and squaring, slicing, bevel grinding, lapping, etching and polishing of the wafer.

To use such wafers as templates for repeated semiconductor material deposition and removal/release processes cost effectively, it is necessary to keep manufacturing cost of such templates at a minimum. Because lapping, grinding and/or polishing present substantial components of cost, it is desirable to avoid these steps all together or to replace them with cheaper steps.

Further, thin film or thin foil solar cells substrates may be generated using a starting substrate that, after slicing and optional bevel grinding, receives a saw damage removal etch. However, such thin film solar cell substrates carry forth the residual template topography from the saw marks even though associated sub-surface damage is removed. Such residual topography may or may not be desirable.

As part of the deposition process for thin film semiconductor solar cell substrates, high volume, low cost epitaxial reactors have been developed. Such reactors allow for the deposition of smooth films with planarizing characteristics at low cost.

Therefore, in order to reduce the manufacturing costs of relatively smooth wafers, the process may be carried out such that as-sliced wafers, after optional bevel treatment, saw damage removal, and cleaning receive an epitaxial layer deposition with a dopant level resembling or close to the level of the starting wafer. FIG. 9A-C depict some of the key fabrication steps of this process. FIG. 9A shows wafer 320 with slicing saw marks 322 and sub-surface damage 324 created from slicing the wafer from an ingot. FIG. 9B depicts wafer 320 after a saw damage removal etch operates to remove sub-surface damage 324 but not slicing saw marks 322. FIG. 9C shows template 320 after saw damage removal etch and a front/top side epi deposition of layer 326 which has like doping as wafer 320. The planarization effect of epitaxial deposition of layer 326 provides smoothed surface topography 328 over the slicing saw marks shown in FIG. 9A-B and allows for further template processing. The wafer surface after this deposition can then be used to form and release smooth thin film semiconductor solar cell substrates or may be processed to form a textured pattern or three-dimensional surface features. The epitaxial layer deposition is depicted on one side of a wafer. It is, however, also envisioned to perform such depositions either subsequentially or at the same time on both sides of a wafer, for instance to allow for forming porous semiconductor release layers on both sides of a wafer or template and later harvesting solar cells from both sides of the template.

As an additional benefit, unlike wafer lapping, grinding or polishing, which all consume silicon in the process and thin down the wafer, the use of a deposited film actually thickens the wafer, thereby rendering it usable for a larger number of re-use cycles.

From the aforementioned disclosures, other advantages of depositing epitaxial layers of suitable thickness and doping type and level for the formation of templates for solar cell substrate production, as well as for other fields, such as the fabrication of micro-electro-mechanical structures (MEMS) can be derived by those skilled in the art.

The disclosed subject matter pertains to deposition of thin film or thin foil materials in general, but more specifically to deposition of epitaxial monocrystalline or quasi-monocrystalline silicon film (epi film) for use in manufacturing of high efficiency solar cells. In operation, methods are disclosed which extend the reusable life and to reduce the amortized cost of a substrate or template used in the manufacturing process of silicon solar cells. Further, methods are disclosed which provide for the conversion of a low quality starting surface into an improved quality starting surface of a silicon wafer.

Those with ordinary skill in the art will recognize that the disclosed embodiments have relevance to a wide variety of areas in addition to those specific examples described above.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

It is intended that all such additional systems, methods, features, and advantages that are included within this description be within the scope of the claims.

What is claimed is:

1. A method for making a thin film crystalline semiconductor substrate, said method comprising:
providing a reusable doped crystalline semiconductor template;
forming a porous semiconductor sacrificial release layer on a front side of said reusable crystalline semiconductor template;
epitaxially depositing a thin film semiconductor substrate conformally to said sacrificial release layer;
releasing said thin film semiconductor substrate from said reusable semiconductor template by separation at said porous semiconductor layer; and
epitaxially depositing a thickening layer of semiconductor material on said front side of said template, said thickening layer being a like material and having a like polarity as said template.

2. The method of claim 1, wherein additional device processing steps are performed after said epitaxially depositing a thin film semiconductor substrate step and prior to said releasing process step.

3. The method of claim 1, wherein said epitaxially depositing a thickening layer of semiconductor material is performed once after a plurality of said epitaxially depositing a thin film semiconductor substrate and subsequently releasing said thin film semiconductor substrate process cycles.

4. The method of claim 1, wherein said thin film crystalline semiconductor substrate is used for fabrication of a solar cell.

5. The method of claim 1, wherein laser processing is utilized prior to said step of releasing said thin film semiconductor substrate from said reusable semiconductor template by separation at said porous semiconductor layer.

6. The method of claim 1, wherein said crystalline semiconductor comprises crystalline silicon.

7. The method of claim 6, wherein said crystalline silicon comprises monocrystalline silicon.

8. The method of claim 1, wherein reusable doped crystalline semiconductor template comprises a substantially planar surface for the formation of said thin film crystalline semiconductor substrate.

9. The method of claim 1, wherein reusable doped crystalline semiconductor template comprises a textured surface for the formation of said thin film crystalline semiconductor substrate.

10. The method of claim 1, wherein reusable doped crystalline semiconductor template comprises a three-dimensional surface topography for the formation of said thin film crystalline semiconductor substrate.

11. The method of claim 10, wherein said three-dimensional surface topography comprises surface cavities and ridges defining the openings of said surface cavities.

12. The method of claim 11, wherein said step of epitaxially depositing a thickening layer of semiconductor material on said front side of said template restores said ridges to a position substantially planar to the front side edge of said template.

13. The method of claim 1, wherein said doped semiconductor template is lightly doped and said thickening layer of semiconductor material is more highly doped to facilitate producing said porous semiconductor material.

14. The method of claim 1, further comprising using bevel grinding of said template containing said epitaxially deposited thin film semiconductor substrate to define a boundary of said thin film semiconductor substrate prior to said step of releasing, thereby aiding said step of releasing.

15. The method of claim 1, further comprising the step polishing or grinding said thickening layer of semiconductor material from a beveled edge of said reusable semiconductor template, thereby strengthening said template.

16. The method of claim 1, wherein said step of epitaxially depositing a thickening layer of semiconductor material on said front side of said template is performed after it is determined the thickness of said reusable doped semiconductor template is below a predetermined threshold.

17. The method of claim 1, wherein said step of epitaxially depositing a thickening layer of semiconductor material on said front side of said template is performed when there exists an epitaxial layer on said front side of said reusable semiconductor template with a dopant non-suitable for porous semiconductor layer formation.

18. The method of claim 1, wherein said step of releasing said thin film semiconductor substrate from said reusable semiconductor template by separation at said porous semiconductor layer further comprises utilizing laser processing.

19. A method for smoothing a wafer surface, said method comprising:
performing a saw damage removal etch on a doped wafer sliced from an ingot; and
epitaxially depositing a planarizing layer of semiconductor material on said wafer, said planarizing layer being a like material and having a like polarity as said wafer.

20. The method of claim 19, wherein said wafer is a monocrystalline silicon wafer.
